(19) United States
(12) Patent Application Publication
(10) Pub. No.: US 2026/0182308 A1
(43) Pub. Date: Jun. 25, 2026

(54) SUBSTRATE PROCESSING METHOD, SUBSTRATE PROCESSING DEVICE, LITHOGRAPHY DEVICE, AND ARTICLE MANUFACTURING METHOD

(71) Applicant: CANON KABUSHIKI KAISHA, Tokyo (JP)

(72) Inventor: GENICHIROU KIYOTA, Tochigi (JP)

(21) Appl. No.: 19/415,552

(22) Filed: Dec. 10, 2025

(30) Foreign Application Priority Data
Dec. 20, 2024 (JP) 2024-224827

(51) Int. Cl. H10P 74/20; G03F 9/00; H10P 72/50

(52) U.S. Cl. CPC H10P 74/203; G03F 9/7046; H10P 72/53

(57) ABSTRACT

A substrate processing method of processing a substrate includes: performing a measurement of a light intensity distribution which is acquired from a peripheral edge portion of the substrate when the peripheral edge portion is irradiated with light from a light source unit; and identifying candidates for a peripheral edge position of the substrate on the basis of a result of the performing the measurement. A plurality of types of the results of the measurement are acquired by performing the measurement using a plurality of types of measuring conditions in one time of the measurement, and the candidates are identified from the plurality of types of results of the measurement.

### BACKGROUND

### Field of the Technology

The present disclosure relates to a substrate processing method, a substrate processing device, a lithography device, and an article manufacturing method.

### Description of the Related Art

In a lithography device that forms a pattern on a substrate, a process of detecting a position of a substrate (a so-called pre-alignment process) is performed before the substrate is carried onto a stage for holding a substrate. In the pre-alignment process, a peripheral edge position of a substrate is detected by irradiating the peripheral edge portion of the substrate with light, and a position (a direction or a center position) of the substrate is determined on the basis of the detected peripheral edge position of the substrate. Accordingly, it is possible to control positioning of the substrate when the substrate is carried onto the stage. In the pre-alignment process, a cutout portion formed in a substrate may be detected.

Substrates on which the pre-alignment process is performed include a plurality of types such as a transparent substrate, an opaque substrate, and a substrate in which a plurality of members are bonded. When a substrate type is changed, a trend of a light intensity distribution acquired from a peripheral edge portion of a substrate can be changed. Accordingly, parameters for determining a position of a substrate from a light intensity distribution may be selected according to a type of the substrate in order to accurately detect a position of a substrate even when the type of the substrate is changed. In Japanese Unexamined Patent Publication No. 2003-282427, a plurality of parameters is applied to outer peripheral measurement of detecting a peripheral edge portion of a substrate, and parameters allowing detection of the peripheral edge portion are selected.

However, in Japanese Unexamined Patent Publication No. 2003-282427, since a plurality of parameters is applied, it is necessary to repeat switching of parameters and re-measurement, which is disadvantageous in throughput.

### SUMMARY

The present disclosure is directed to provide a technique which is advantageous for making a throughput and detection accuracy compatible at the time of detection of a position of a substrate.

According to an aspect of the present disclosure, a substrate processing method is a substrate processing method of processing a substrate, the substrate processing method including: performing a measurement of a light intensity distribution which is acquired from a peripheral edge portion of the substrate when the peripheral edge portion is irradiated with light from a light source unit; and identifying candidates for a peripheral edge position of the substrate on the basis of a result of the performing the measurement, wherein a plurality of types of the results of the measurement are acquired by performing the measurement using a plurality of types of measuring conditions in one time of the measurement, and the candidates are identified from the plurality of types of results of the measurement.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram schematically illustrating an example of a configuration of a substrate processing device.

FIG. 2 is a diagram illustrating an example in which a peripheral edge position of a substrate is detected.

FIG. 3 is a diagram illustrating an example in which a peripheral edge position of a substrate is detected.

FIG. 4 is a diagram illustrating an example in which a peripheral edge position of a substrate is detected.

FIG. 5 is a diagram illustrating an example in which a peripheral edge position of a substrate is detected.

FIG. 6 is a diagram illustrating an example in which a peripheral edge position of a substrate is detected.

FIGS. 7A and 7B are diagrams illustrating an example of a position waveform and an ideal position waveform indicating an outer shape of a substrate.

FIG. 8 is a diagram illustrating Expression (1).

FIG. 9 is a flowchart illustrating an operation flow of a pre-alignment process according to a first embodiment.

FIGS. 10A to 10E are diagrams illustrating an example of a method of selecting an optical measuring condition.

FIGS. 11A and 11B are diagrams illustrating an example of a method of selecting an optical measuring condition.

FIG. 12 is a diagram illustrating an example of a method of selecting an optical measuring condition.

FIG. 13 is a flowchart illustrating an operation flow of a pre-alignment process according to a second embodiment.

FIG. 14 is a flowchart illustrating an operation flow of a pre-alignment process according to a third embodiment.

FIGS. 15A to 15E are diagrams illustrating an example of a cutout waveform and an ideal cutout waveform corresponding to a cutout of a substrate.

FIG. 16 is a flowchart illustrating an operation flow of a pre-alignment process according to a fourth embodiment.

FIG. 17 is a diagram schematically illustrating an example of a configuration of an exposure device.

### DESCRIPTION OF THE EMBODIMENTS

Hereinafter, embodiments will be described in detail with reference to the accompanying drawings. The following embodiments are not intended to limit the present disclosure described in the appended claims. A plurality of features are described in the embodiments, all of the plurality of features are not essential to the present disclosure, and the plurality of features may be arbitrarily combined. In the drawings, the same or similar elements will be referred to by the same reference signs, and repeated description thereof will be omitted.

In this specification and the accompanying drawings, directions in an XYZ coordinate system in which directions parallel to a holding surface for allowing a substrate chuck 123 which will be described later to hold a substrate are defined as an XY plane are described unless otherwise mentioned. Directions parallel to an X axis, a Y axis, and a Z axis in the XYZ coordinate system are defined as an X direction, a Y direction, and a Z direction, and rotation around the X axis, rotation around the Y axis, and rotation around the Z axis are defined as OX, OY, and OZ. Control or driving with respect to the X axis, the Y axis, and the Z axis means control or driving in a direction parallel to the X axis, a direction parallel to the Y axis, and a direction parallel to the Z axis. Control or driving around the OX axis, the OY axis, and the OZ axis means control or driving in rotation around an axis parallel to the X axis, rotation around an axis parallel to the Y axis, and rotation around an axis parallel to the Z axis. A position is information which can be identified on the basis of coordinates in the X axis, the Y axis, and the Z axis and a direction is information which can be identified by values around the OX axis, the OY axis, and the OZ axis.

### First Embodiment

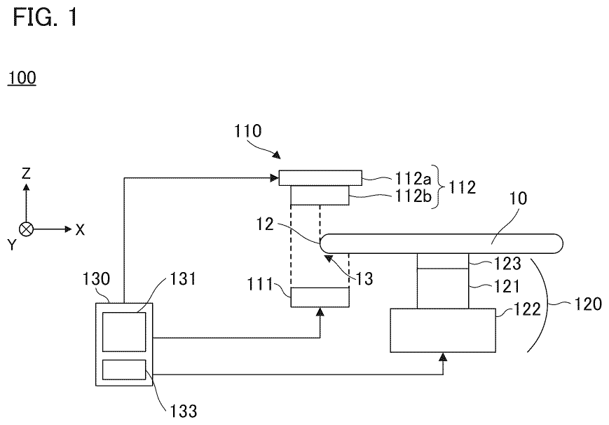

A first embodiment of the present disclosure will be described below. FIG. 1 is a diagram schematically illustrating a substrate processing device 100 according to the first embodiment. The substrate processing device 100 includes a light source unit 111, a substrate holding unit 120, a measurement unit 110, and a control unit 130. FIG. 1 illustrates a state in which a substrate 10 is placed on the substrate holding unit 120.

The substrate processing device 100 according to the present embodiment is a device that performs a process (a so-called pre-alignment process) of detecting a position of a peripheral edge 12 of a substrate 10 before carrying the substrate 10 onto a substrate stage of a lithography device. In the pre-alignment process, the position of the peripheral edge 12 of the substrate 10 is detected on the basis of alight intensity distribution acquired from a peripheral edge portion 13 of the substrate 10 when the peripheral edge portion 13 is irradiated with light. By determining a direction or a center position of the substrate 10 on the basis of the position of the peripheral edge 12 of the substrate 10 detected in the pre-alignment process, it is possible to control positioning of the substrate 10 when the substrate 10 is carried onto the substrate stage of the lithography device. Positioning of the substrate 10 is adjusting (disposing) the substrate 10 to have a predetermined position or orientation in a translational direction (for example, the XY directions) and a rotational direction (for example, the OZ direction) and may be referred to as “alignment of the substrate 10.” The substrate processing device 100 that performs the pre-alignment process may be referred to as a “pre-alignment device” or a “substrate alignment device.”

The substrate holding unit 120 is a mechanism for holding or driving the substrate 10 and includes a substrate chuck 123, a rotational driving unit 121, and a translational driving unit 122. The substrate chuck 123 holds a central portion of the substrate 10 with a holding surface parallel to the XY plane using a vacuum suction force, an electrostatic suction force, or the like. The rotational driving unit 121 rotationally drives the substrate 10 in the OZ direction by rotationally driving the substrate chuck 123 in the OZ direction with the Z axis as a rotational axis. The translational driving unit 122 translationally drives the substrate 10 in the XY directions by translationally driving the substrate chuck 123 and the rotational driving unit 121 in the XY directions.

In the present embodiment, the substrate 10 held by the substrate holding unit 120 includes a cutout on the peripheral edge portion 13. The cutout of the substrate 10 may be a notch or an orientation flat. Here, the substrate 10 may be a substrate not including a cutout. The type of the substrate 10 which is held by the substrate holding unit 120 and on which the pre-alignment process is performed is arbitrary. That is, the substrate processing device 100 according to the present embodiment can perform a pre-alignment process on various types of substrates 10 regardless of a material, transparency, whether chamfering has been performed, whether bonding has been performed, or the like.

The measurement unit 110 is a mechanism for measuring a light intensity distribution acquired from the peripheral edge portion 13 when the peripheral edge portion 13 of the substrate 10 is irradiated with light and includes a light source unit 111 and a light receiving unit 112 (a light receiving element or a light receiving sensor). For example, the light source unit 111, disposed on a rear surface side (a lower side) of the substrate 10, irradiates the peripheral edge portion 13 with light such that the peripheral edge portion 13 of the substrate 10 is disposed in only apart of an optical path. For example, an LED light source is herein used as the light source unit 111, and, for example, a laser light source or a fluorescence lamp may be used.

For example, the light receiving unit 112 is disposed on a front surface side (an upper side) of the substrate 10 to face the light source unit 111 (a light emission surface) and receives light emitted from the light source unit 111. The light receiving unit 112 according to the present embodiment includes a light receiving element 112a (a light receiving sensor) and an optical system 112b. The light receiving element 112a may be an imaging element such as a CCD image sensor or a CMOS image sensor. The optical system 112b is an image-forming optical system for forming an image of the peripheral edge portion 13 of the substrate 10 on a light receiving surface (an imaging surface) of the light receiving element 112a.

When the substrate 10 is an opaque substrate, light passing through a space outside of the substrate 10 out of light emitted from the light source unit 111 is received by the light receiving unit 112. On the other hand, when the substrate 10 is a transparent substrate and the peripheral edge portion 13 thereof is chamfered, light passing through a space outside of the substrate 10 and light passing through a part other than the peripheral edge portion 13 of the substrate 10 out of light emitted from the light source unit 111 are received by the light receiving unit 112. The space outside of the substrate 10 may be understood as a space which is not blocked by the substrate 10.

The measurement unit 110 measures a light intensity distribution in a radial direction (the X direction) acquired from a part of the peripheral edge portion 13 of the substrate 10 on the basis of light received (detected) by the light receiving unit 112 out of light emitted from the light source unit 111. Then, the measurement unit 110 sequentially performs measurement of a light intensity distribution in the radial direction in a state in which the substrate 10 is rotationally driven by the substrate holding unit 120. Accordingly, it is possible to acquire a light intensity distribution in the radial direction for the whole peripheral edge portion 13 of the substrate 10. In the following description, the light intensity distribution in the radial direction may be simply referred to as a “light intensity distribution.”

Here, the measurement unit 110 according to the present embodiment is configured as a transmissive sensor, but is not limited thereto, and the measurement unit 110 may be configured, for example, as a reflective sensor that detects light reflected by the peripheral edge portion 13 of the substrate 10 out of light emitted from the light source unit 111 using the light receiving unit 112. The measurement unit 110 (the light source unit 111) may be a bright-field illumination. By using a bright-field illumination instead of a dark-field illumination, it is possible to curb a decrease in detection accuracy of the position of the peripheral edge 12 of the substrate 10 due to light reflected by a chamfered part even when the peripheral edge portion 13 of the substrate 10 is chamfered.

The control unit 130 can be configured, for example, as a computer (an information processing device) including a processor 131, such as a central processing unit (CPU), and a storage unit 133 such as a memory. The control unit 130 is connected to the constituents of the substrate processing device 100 via lines and controls the constituents of the substrate processing device 100 (controls the pre-alignment process).

In the present embodiment, the constituents of the substrate processing device 100 are controlled by one control unit 130, but the substrate processing device 100 may include a plurality of control units. Specifically, the substrate processing device 100 may include a first control unit that controls the measurement unit 110, a second control unit that controls the substrate holding unit 120, and a third control unit that performs a process of detecting the position of the peripheral edge 12 or the like on the basis of measurement results. In this case, the first to third control units may be communicatively connected to each other to be able to transmit and receive information. For example, the control unit 130 can drive the substrate holding unit 120 to align the substrate 10 such that misalignment of the substrate 10 calculated by the third control unit is corrected. An external memory may be used as the storage unit 133.

In the present embodiment, the control unit 130 (the processor 131) detects the position of the peripheral edge 12 of the substrate 10 on the basis of the light intensity distribution measured by the measurement unit 110 and controls positioning of the substrate 10 on the basis of the detection result. Specifically, the control unit 130 controls the measurement unit 110 such that measurement of the light intensity distribution is performed in a plurality of types of measuring conditions. Then, the control unit 130 identifies candidates for the position of the peripheral edge 12 of the substrate 10 in the radial direction from each of the light intensity distributions acquired in the plurality of types of measuring conditions. Then, the control unit 130 selects one measuring condition for determining the position of the substrate 10 from the plurality of types of measuring conditions on the basis of the plurality of identified candidates and determines the position (the direction or the center position) of the substrate 10 using the one measuring condition. Accordingly, the control unit 130 can accurately perform positioning of the substrate 10 on the basis of the determined position of the substrate 10. Positioning of the substrate 10 may be understood to be driving the substrate 10 such that the substrate 10 is disposed at a predetermined position, that is, such that misalignment of the substrate 10 is decreased.

Information required for performing the pre-alignment process is stored in the storage unit 133. For example, programs for performing a pre-alignment process or a plurality of types of measuring conditions (for example, parameters for setting a measuring condition) used in the pre-alignment process are stored in the storage unit 133. Position information of the peripheral edge 12 of the substrate 10 determined by the processor 131, algorithms which are applied to the light intensity distribution measured by the measurement unit 110, and the like are stored in the storage unit 133. In the following description, the position of the peripheral edge 12 of the substrate 10 in the radial direction may be referred to as a “peripheral edge position.”

### <Detection of Peripheral Edge Position>

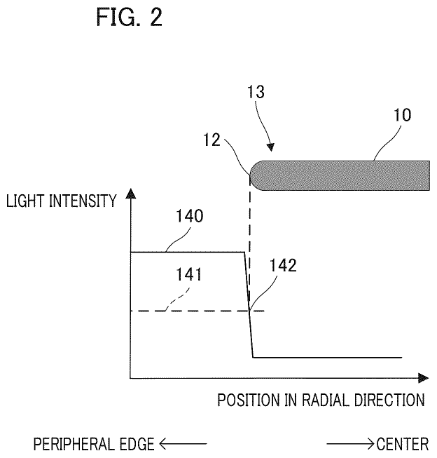

Examples in which a peripheral edge position of a substrate 10 is detected will be described below with reference to FIG. 2 to 6. FIGS. 2 to 6 illustrate an example in which a peripheral edge position of a substrate 10 is detected for each of a plurality of types of substrates 10 which are different in material or structure. In each of FIGS. 2 to 6, a structure of a peripheral edge portion 13 of a substrate 10 and a light intensity distribution acquired from the light receiving unit 112 of the measurement unit 110 corresponding thereto are illustrated. The light intensity distribution is illustrated with a position in the radial direction of the substrate 10 as a horizontal axis and with a received light intensity (light intensity) in the light receiving unit 112 as a vertical axis.

FIG. 2 illustrates an example in which the substrate 10 is an opaque substrate (for example, a silicon substrate) and the peripheral edge portion 13 of the substrate 10 is chamfered. In this example, since apart of light from the light source unit 111 is blocked by the substrate 10, only light passing through a space outside of the peripheral edge 12 of the substrate 10 is incident on the light receiving unit 112 of the measurement unit 110. Accordingly, alight intensity distribution 140 acquired by the light receiving unit 112 has a shape in which a light intensity changes greatly with the peripheral edge 12 of the substrate 10 as a boundary as illustrated in FIG. 2.

In an algorithm for detecting a peripheral edge position of a substrate 10 which is an opaque substrate and in which the peripheral edge portion 13 of the substrate 10 is chamfered, a determination threshold value 141 which is set between a light intensity acquired for the outside of the peripheral edge 12 of the substrate 10 and alight intensity acquired for the inside of the substrate 10 is used. In the algorithm, a position 142 at which the light intensity in the light intensity distribution 140 measured by the measurement unit 110 becomes the determination threshold value 141 is identified as the peripheral edge position of the substrate 10. That is, in the algorithm, a position 142 at which the light intensity in the light intensity distribution 140 measured by the measurement unit 110 first becomes less than the determination threshold value 141 from the peripheral edge of the substrate 10 to the center (the center of gravity) is identified as the peripheral edge position of the substrate 10. In this way, in the example illustrated in FIG. 2, the control unit 130 can detect (identify) the peripheral edge position of the substrate 10 by applying the algorithm using the determination threshold value 141 to the light intensity distribution. When the substrate 10 is an opaque substrate, the peripheral edge 12 of the substrate 10 can be detected regardless of the light intensity of the light source unit 111.

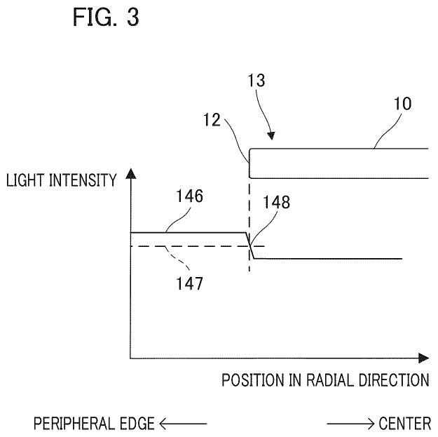

FIG. 3 illustrates an example in which the substrate 10 is a transparent substrate (for example, a glass substrate) and the peripheral edge portion 13 of the substrate 10 has not been chamfered. In this example, light with a normal intensity is emitted from the light source unit 111. In this example, apart of the light from the light source unit 111 passes through the substrate 10, and the light intensity of the part of light decreases (that is, the light attenuates) at that time. Accordingly, a light intensity distribution 146 acquired from the light receiving unit 112 of the measurement unit 110 has a shape in which the light intensity changes with the peripheral edge 12 of the substrate 10 as a boundary as illustrated in FIG. 3. In this example, since light is transmitted by the substrate 10, an amount of change in light intensity in the light intensity distribution 146 is smaller than an amount of change in light intensity in the light intensity distribution 140 illustrated in FIG. 2.

In an algorithm for detecting a peripheral edge position of a substrate 10 in which the substrate 10 is a transparent substrate and in which the peripheral edge portion 13 of the substrate 10 is not chamfered, a determination threshold value 147 which is set between a light intensity acquired for the outside of the peripheral edge 12 of the substrate 10 and a light intensity acquired for the inside of the peripheral edge 12 of the substrate 10 is used. In the algorithm, a position 148 at which the light intensity in the light intensity distribution 146 measured by the measurement unit 110 becomes the determination threshold value 147 is identified as the peripheral edge position of the substrate 10. That is, in the algorithm, a position 148 at which the light intensity in the light intensity distribution 146 measured by the measurement unit 110 first becomes less than the determination threshold value 147 from the peripheral edge of the substrate 10 to the center is identified as the peripheral edge position of the substrate 10. In this way, in the example illustrated in FIG. 3, the control unit 130 can detect (identify) the peripheral edge position of the substrate 10 by applying the algorithm using the determination threshold value 147 to the light intensity distribution.

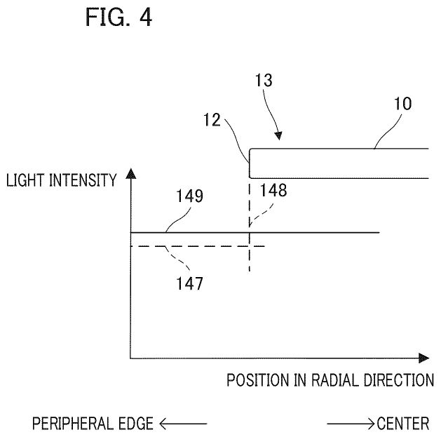

FIG. 4 illustrates an example in which the substrate 10 is a transparent substrate (for example, a glass substrate) and the peripheral edge portion 13 of the substrate 10 has not been chamfered. In this example, unlike the example illustrated in FIG. 3, light with a much higher intensity than a normal intensity is emitted from the light source unit 111. Herein, for example, light with alight intensity which is nine times the normal intensity is emitted. In general, apart of the light from the light source unit 111 passes through the substrate 10, and the light intensity of the part of light decreases (that is, the light attenuates) at that time. However, in this example, since the light intensity of light from the light source unit 111 is high, a light intensity distribution 149 acquired from the light receiving unit 112 of the measurement unit 110 has a constant shape in which the light intensity does not change with the peripheral edge 12 of the substrate 10 as a boundary as illustrated in FIG. 4. This is because the light intensity of light from the light source unit 111 is high and the light intensity is higher than the threshold value of the light intensity which can be measured by the light receiving unit 112 even after the light attenuates due to the substrate 10. When the light receiving unit 112 receives light with a light intensity greater than the threshold value for the measurable intensity, the light intensity is saturated, and an acquired waveform does not increase any more. In the example illustrated in FIG. 4, when the same algorithm (the determination threshold value 147) as in the example illustrated in FIG. 3 is used, it is not possible to detect (identify) the peripheral edge position of the substrate 10.

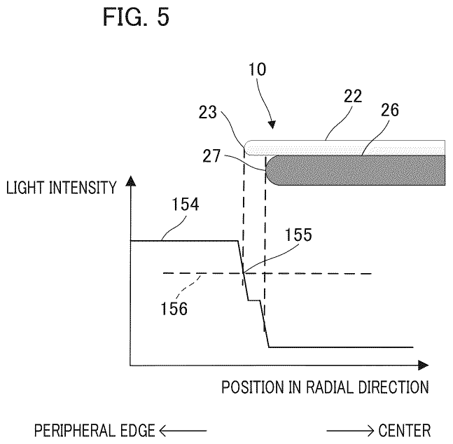

FIG. 5 illustrates an example in which the substrate 10 is a substrate including an opaque substrate 26 (for example, a silicon substrate) and a transparent film 22 bonded thereon. The outer shape of the transparent film 22 is larger than the opaque substrate 26. The peripheral edge portion of the opaque substrate 26 is chamfered. In this example, a part of light from the light source unit 111 is blocked by the opaque substrate 26. The part of light passing through the outside of a peripheral edge 27 of the opaque substrate 26 passes through the transparent film 22, and the light intensity of the part of light decreases (that is, the light attenuates) at that time. Accordingly, a light intensity distribution 154 acquired from the light receiving unit 112 of the measurement unit 110 has the shape illustrated in FIG. 5.

In the example illustrated in FIG. 5, a determination threshold value 156 is used in an algorithm for detecting a peripheral edge position of the opaque substrate 26. The determination threshold value 156 is set between a light intensity acquired for the outside of a peripheral edge 23 of the transparent film 22 and a light intensity acquired for the inside of the opaque substrate 26. In the algorithm, a position 155 at which the light intensity in the light intensity distribution 154 measured by the measurement unit 110 becomes the determination threshold value 156 can be erroneously identified as the peripheral edge position of the opaque substrate 26.

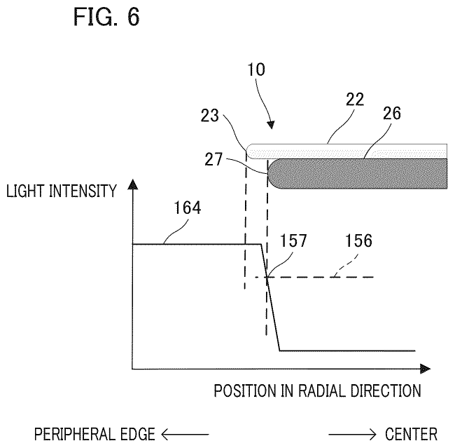

FIG. 6 illustrates an example in which the substrate 10 is a substrate including an opaque substrate 26 (for example, a silicon substrate) and a transparent film 22 bonded thereon. In this example, light with a higher intensity than a normal light intensity is emitted from the light source unit 111. Here, for example, light with a light intensity which is nine times the normal intensity is emitted. In general, a part of the light from the light source unit 111 passes through the transparent film 22, and the light intensity of the part of light decreases (that is, the light attenuates) at that time. However, in this example, since the light intensity of light from the light source unit 111 is high, a light intensity distribution 164 acquired from the light receiving unit 112 of the measurement unit 110 does not change with a peripheral edge 23 of the transparent film 22 as a boundary as illustrated in FIG. 6. This is because the light intensity of light from the light source unit 111 is high and the light intensity is higher than the threshold value of the light intensity which can be measured by the light receiving unit 112 even after the light attenuates due to the transparent film 22. Since a part of light from the light source unit 111 is further blocked by the opaque substrate 26, light passing through a space outside of the peripheral edge 23 of the transparent film 22 and light passing through the transparent film 22 are incident on the light receiving unit 112 of the measurement unit 110. Accordingly, the light intensity distribution 164 acquired from the light receiving unit 112 has a shape in which the light intensity changes greatly with the peripheral edge 27 of the opaque substrate 26 as a boundary as illustrated in FIG. 6.

In the algorithm, a position 157 at which the light intensity in the light intensity distribution 164 measured by the measurement unit 110 becomes the determination threshold value 156 is identified as the peripheral edge position of the opaque substrate 26. That is, in the algorithm, the position 157 at which the light intensity in the light intensity distribution 164 measured by the measurement unit 110 first becomes less than the determination threshold value 156 from the peripheral edge to the center of the opaque substrate 26 is identified as the peripheral edge position of the opaque substrate 26.

As described above, the light intensity distribution measured by the measurement unit 110 (the light receiving unit 112) changes according to a material and transparency (transparent/opaque) of the substrate 10, whether the peripheral edge portion 13 has been chamfered, and whether bonding has been performed. That is, when the type of the substrate 10 changes, a trend of the light intensity distribution measured by the measurement unit 110 can change. Accordingly, in order to accurately detect the peripheral edge position of the substrate 10 even when the type of the substrate 10 changes, it is necessary to appropriately select a measuring condition at the time of acquisition of the light intensity distribution according to the type of the substrate. However, when the process of measuring the light intensity distribution using the measurement unit 110 while rotationally driving the substrate 10 is performed a plurality of times while changing the measuring condition, it may cause disadvantages in view of the throughput. That is, in the pre-alignment process, the throughput and the detection accuracy may be made compatible at the time of detection of the position of the substrate 10. Accordingly, in the present embodiment, by applying a plurality of types of measuring conditions to one time of measurement using the measurement unit 110, a plurality of types of light intensity distributions (measurement results) are acquired, and candidates for the peripheral edge position of the substrate 10 are identified from the plurality of light intensity distributions. Then, one measuring condition which is used to determine the position of the substrate 10 is selected out of the plurality of types of measuring conditions on the basis of the plurality of identified candidates. In the following description, the candidates for the peripheral edge position of the substrate 10 may be referred to as “peripheral edge position candidates.”

Here, the plurality of types of measuring conditions may include, for example, at least two types of measuring conditions which are different in at least one of a light intensity, a wavelength, and an irradiation direction of light emitted from the light source unit 111 and a threshold value for a light intensity which can be measured by the light receiving unit 112. For example, the measuring conditions used in the examples illustrated in FIGS. 3 and 4 may be different in light intensity of light emitted from the light source unit 111.

### <Selection of Measuring Condition>

Selection of a measuring condition can be performed, for example, by calculating an evaluation value for each of the plurality of peripheral edge position candidates. The evaluation value for each of the plurality of peripheral edge position candidates can be calculated on the basis of at least one of similarity between an outer shape of the substrate 10 acquired from the peripheral edge position and a first reference shape and roundness of the outer shape of the substrate 10 acquired from the peripheral edge position. The evaluation value may be calculated additionally or alternatively on the basis of similarity between a shape of the cutout of the substrate 10 acquired from the peripheral edge position and a second reference shape.

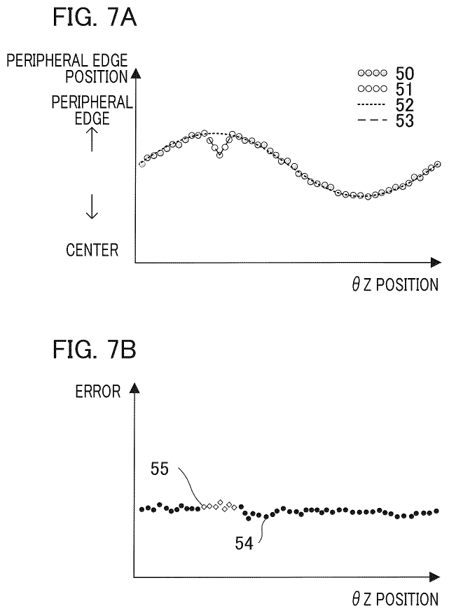

The control unit 130 can acquire a position waveform 50 indicating a relationship between a position in the θZ direction (the peripheral direction) and the peripheral edge position as illustrated in FIG. 7A by causing the measurement unit 110 to sequentially measure the light intensity distribution in the radial direction while rotationally driving the substrate 10 using the substrate holding unit 120. In FIG. 7A, the horizontal axis represents a position in the θZ direction of the peripheral edge portion 13 (that is, a rotational angle θ of the substrate 10) in which measurement of the light intensity distribution has been performed by the measurement unit 110, and the vertical axis represents a peripheral edge position in the radial direction identified from the light intensity distribution measured by the measurement unit 110. The position waveform 50 may be understood as representing the outer shape of the substrate 10 acquired from the detection result of the peripheral edge position. The position waveform 50 includes a partial waveform 51 corresponding to the cutout of the substrate 10. An example in which the cutout of the substrate 10 is a notch is illustrated in FIG. 7A.

For example, the control unit 130 can calculate the evaluation value on the basis of at least one of similarity between the position waveform 50 indicating the outer shape of the substrate 10 and an ideal position waveform 52 indicating an ideal outer shape of the substrate 10 and roundness of the outer shape of the substrate 10 acquired from the position waveform 50. The similarity between the position waveform 50 and the ideal position waveform 52 can be calculated on the basis of an error 54 between the position waveform 50 and the ideal position waveform 52 illustrated in FIG. 7B. The ideal position waveform 52 is a waveform indicating the ideal outer shape of the substrate 10 and may also be understood as a reference shape (a first reference shape) for the outer shape of the substrate 10. The control unit 130 can acquire the ideal position waveform 52 using Expression (1) by calculating an eccentricity (X, Y) and a rotational angle θ of the substrate 10 with respect to a rotation center 125 of the substrate 10 by the substrate holding unit 120 on the basis of the position waveform 50.

$$[ Math . 1 ]$$

$$f ( θ ) = r cos ( θ + α ) + \sqrt{{L}^{2} - \{ r {sin ( θ + α )}^{2} \}} \qquad ( 1 )$$

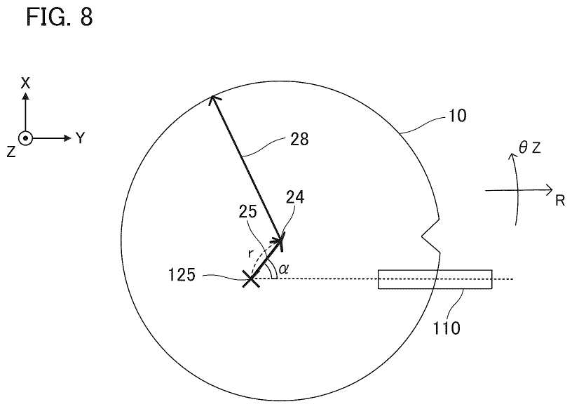

Expression (1) will be described below with reference to FIG. 8. In FIG. 8, the θZ direction indicates the peripheral direction of the substrate 10, and the R direction indicates the radial direction of the substrate 10. When the center of gravity 24 (the center) of the substrate 10 is eccentric from the rotation center 125 of the substrate 10 by the substrate holding unit 120 as illustrated in FIG. 8, “r” indicates the magnitude of an eccentricity vector 25 (a distance between the rotation center 125 and the center of gravity 24 of the substrate 10). “θ” indicates the rotation angle of the substrate 10 by the substrate holding unit 120. The rotational angle θ may be understood as a position in the θZ direction of the peripheral edge portion 13 at which the light intensity distribution is measured by the measurement unit 110. “α” indicates an angle formed by a straight line connecting the rotation center 125 and the light receiving unit 112 (the light receiving element 112a) and the eccentricity vector 25 when the straight line is defined. “L” indicates a radius 28 of the substrate 10.

The control unit 130 may calculate the evaluation value on the basis of similarity between a partial waveform 51 indicating the shape of the cutout of the substrate 10 and an ideal partial waveform 53 indicating an ideal outer shape of the cutout as illustrated in FIG. 7A. The similarity between the partial waveform 51 and the ideal partial waveform 53 can be calculated on the basis of an error 55 between the partial waveform 51 and the ideal partial waveform 53 illustrated in FIG. 7B. The ideal partial waveform 53 may be understood as a reference shape (a second reference shape) for the outer shape of the cutout of the substrate 10 and can be acquired from design information (design data or size information) of the cutout of the substrate 10.

### <Operation Flow of Pre-Alignment Process>

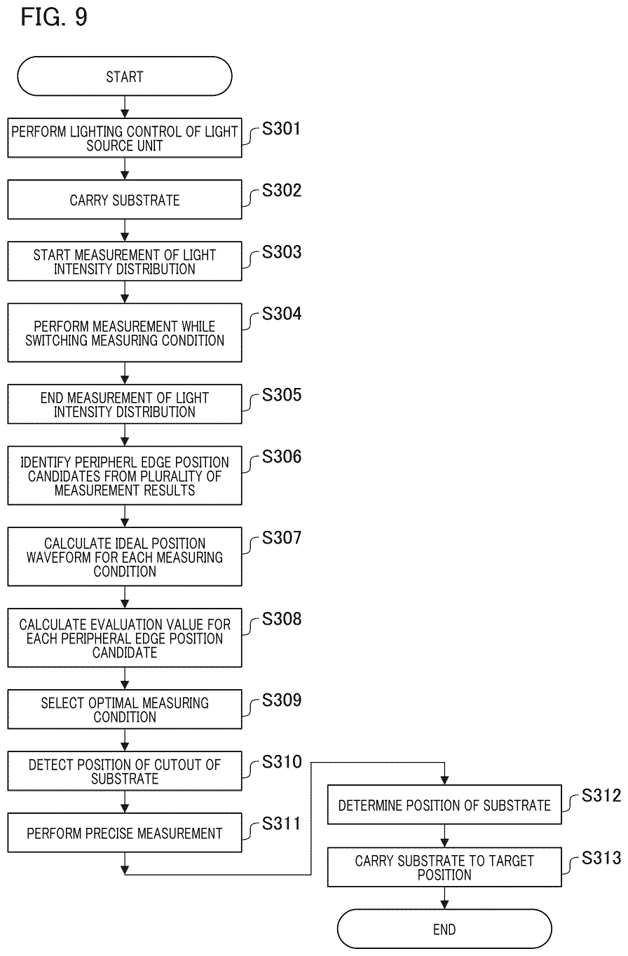

An operation flow of a pre-alignment process according to the present embodiment will be described below. FIG. 9 is a flowchart illustrating an operation flow of the pre-alignment process according to the present embodiment. The flowchart illustrated in FIG. 9 can be performed by the control unit 130.

In Step S301, the control unit 130 performs lighting control of the light source unit 111 in the measurement unit 110 before a substrate 10 is carried onto the substrate holding unit 120 of the substrate processing device 100. Lighting control of the light source unit 111 may be performed in a state in which the substrate 10 serving as alight blocking object is not located in an optical path. When lighting control of the light source unit 111 is performed after a substrate 10 has been carried onto the substrate holding unit 120, an amount of light in apart blocked by the substrate 10 cannot be ascertained. As a result, there is concern that a signal intensity may be greater than allowable value while rotationally moving the substrate 10.

In Step S302, the control unit 130 carries the substrate 10 onto the substrate holding unit 120 of the substrate processing device 100 using a substrate carrying mechanism (a substrate carrying robot) which is not illustrated. The substrate 10 carried onto the substrate holding unit 120 is held by the substrate chuck 123. In the step in which the substrate 10 has been carried onto the substrate holding unit 120, the substrate 10 has not been positioned, and the substrate 10 is offset in the translational direction and the rotational direction from a desired position on the substrate holding unit 120.

Steps S303 to S305 constitute a step of measuring a light intensity distribution using the measurement unit 110 (a first measurement step). In Step S303, the control unit 130 starts rotational driving of the substrate 10 in the θZ direction using the substrate holding unit 120 (the rotational driving unit 121) and starts measurement of a light intensity distribution of the peripheral edge portion 13 of the substrate 10 using the measurement unit 110. In Step S304, the control unit 130 controls, for example, the light source unit 111 such that the light intensity distribution is measured while periodically and alternately switching two or more types of measuring conditions. The control unit 130 sequentially acquires information (data) of the light intensity distribution measured by the measurement unit 110 from the measurement unit 110 and stores the acquired information in the storage unit 133. Subsequently, in Step S305, the control unit 130 ends the rotational driving of the substrate 10 using the substrate holding unit 120 and measurement of the light intensity distribution using the measurement unit 110 when the substrate 10 is rotated by an amount of rotation (for example, 360 degrees) required for determining the position of the substrate 10. The measurement of the light intensity distribution is performed in a state in which the substrate 10 has been rotationally driven in the θZ direction by the substrate holding unit 120 (the rotational driving unit 121). That is, the measurement unit 110 sequentially (continuously) performs the measurement of the light intensity distribution in the radial direction of a part of the peripheral edge portion 13 of the substrate 10 while rotationally driving the substrate 10 using the substrate holding unit 120. Accordingly, the control unit 130 can obtain the light intensity distribution in the radial direction as a whole of the peripheral edge portion 13 of the substrate 10. The light intensity distribution is obtained for each measuring condition, and thus the light intensity distributions corresponding to the number of types of the measuring conditions can be obtained.

In Step S306, the control unit 130 identifies peripheral edge position candidates for each of the plurality of types of light intensity distributions acquired in Step S303 to S305 (an identification step). Specifically, the control unit 130 classifies the light intensity distributions acquired under a plurality of types of measuring conditions according to the measuring conditions and calculates the position waveform 50 illustrated in FIG. 7A for each of the classified light intensity distributions. As described above, the position waveform 50 is a waveform indicating a relationship between a position in the θZ direction of the substrate 10 and a peripheral edge position and may be understood as representing the outer shape of the substrate 10. The position waveform 50 may include a partial waveform 51 corresponding to a cutout of the substrate 10. For example, the control unit 130 plots the peripheral edge position candidates of the substrate 10 identified for each measuring condition to correspond to the position in the θZ direction of the substrate 10. Accordingly, the control unit 130 can calculate the position waveform 50 for each measuring condition.

In Step S307, the control unit 130 calculates an ideal position waveform 52 for each measuring condition. Specifically, the ideal position waveform 52 for each measuring condition is calculated by calculating the eccentricity (X, Y) and the rotational angle θ of the substrate 10 with respect to the rotation center 125 of the substrate 10 using the substrate holding unit 120 on the basis of the position waveform 50 for each measuring condition as described above.

In Step S308, the control unit 130 calculates an evaluation value for each of a plurality of peripheral edge position candidates (an evaluation step). Step S308 may be understood as a step of calculating an evaluation value for each of a plurality of types of measuring conditions. In the present embodiment, the control unit 130 can calculate the evaluation value on the basis of at least one of the similarity between the position waveform 50 and the ideal position waveform 52, the roundness of the outer shape of the substrate 10 acquired from the position waveform 50, and the similarity between the partial waveform 51 and the ideal partial waveform 53. For example, the control unit 130 can calculate the evaluation value by calculating the similarity between the position waveform 50 and the ideal position waveform 52 from a sum value or a variance value of the errors 54 between the position waveform 50 and the ideal position waveforms 52 illustrated in FIG. 7B. Alternatively, the control unit 130 can calculate the evaluation value by calculating the roundness from an error between the outer shape of the substrate 10 acquired from the position waveform 50 and a perfect circle. The control unit 130 may calculate the evaluation value by calculating the similarity between the partial waveform 51 and the ideal partial waveform 53 from a sum value or a variance value of the error 55 between the partial waveform 51 and the ideal partial waveform 53 illustrated in FIG. 7B.

Here, the control unit 130 may calculate the evaluation value on the basis of a plurality of evaluation indices acquired from the peripheral edge position candidates. The plurality of evaluation indices can include at least two of the similarity between the position waveform 50 and the ideal position waveform 52, the roundness of the outer shape of the substrate 10 acquired from the position waveform 50, and the similarity between the partial waveform 51 and the ideal partial waveform 53. In this case, the control unit 130 may weigh the plurality of evaluation indices and calculate the evaluation value on the basis of the result. For example, the control unit 130 can calculate a sum of the plurality of weighted evaluation indices as the evaluation value.

In Step S309, the control unit 130 selects one measuring condition used to determine the position of the substrate 10 out of a plurality of types of measuring conditions as an optimal measuring condition on the basis of the evaluation value calculated for each peripheral edge position candidate in Step S308 (a selection step). For example, the control unit 130 can select a peripheral edge position candidate with the best evaluation value out of the plurality of peripheral edge position candidates and select the measuring condition used to identify the selected peripheral edge position candidate as an optimal measuring condition. Specifically, when the sum value of the errors 54 between the position waveform 50 and the ideal position waveform 52 is calculated as an evaluation value, the control unit 130 can select the measuring condition for the light intensity distribution used to identify a peripheral edge position candidate with the smallest evaluation value out of the plurality of peripheral edge position candidates as an optimal measuring condition. On the other hand, when a reciprocal of the sum value of the errors 54 between the position waveform 50 and the ideal position waveform 52 is calculated as an evaluation value, the control unit 130 can select a measuring condition used to identify a peripheral edge position candidate with the largest evaluation value out of the plurality of peripheral edge position candidates as an optimal measuring condition.

Steps S310 to S313 constitute a step of controlling positioning of the substrate 10 using the measuring condition selected in Step S309. The positioning of the substrate 10 in the present embodiment can include positioning of the substrate 10 in a state in which it is held by the substrate holding unit 120 and positioning of the substrate 10 when the substrate 10 is carried from the substrate holding unit 120 to a target position. The target position is, for example, a position on the substrate stage of the lithography device.

In Step S310, the control unit 130 detects a position of the peripheral edge portion 13 (for example, a cutout) of the substrate 10 in a state in which it is held by the substrate holding unit 120 on the basis of the peripheral edge position candidate identified according to the optimal measuring condition.

Subsequently, in Step S311, the control unit 130 performs precise measurement (a second measurement step) of re-measuring the light intensity distribution of the peripheral edge portion 13 of the substrate 10 under the optimal measuring condition using the measurement unit 110. In the precise measurement, first, the control unit 130 performs positioning of the substrate 10 such that the peripheral edge portion 13 (the cutout) of the substrate 10 is disposed in an optical path of the measurement unit 110 on the basis of the position of the peripheral edge portion 13 (the cutout) of the substrate 10 detected in Step S310. The positioning of the substrate 10 may be performed by translationally moving and rotationally driving the substrate 10 using the substrate holding unit 120 or may be performed by placing the substrate 10 on the substrate holding unit 120 again using a substrate carrying mechanism (a substrate carrying robot) which is not illustrated. Then, the control unit 130 sequentially measures the light intensity distribution of the peripheral edge portion 13 of the substrate 10 under the optimal measuring condition using the measurement unit 110 while rotationally driving the substrate 10 using the substrate holding unit 120. In the present embodiment, the control unit 130 can precisely measure the light intensity distribution of the cutout in the peripheral edge portion 13 of the substrate 10. By performing this precise measurement, it is possible to curb a decrease in processing precision due to misalignment of the substrate 10 in a substrate carrying operation or a processing operation which is subsequently performed.

In Step S312, the control unit 130 determines the position of the substrate 10 (a determination step). Specifically, the control unit 130 identifies a peripheral edge position of the substrate 10 by applying a predetermined algorithm to the light intensity distribution acquired in Step S111. Then, the control unit 130 calculates a position waveform 50 at the identified peripheral edge position of the substrate 10 and determines the position of the substrate 10 on the basis of the position waveform 50. The position of the substrate 10 determined in Step S112 can include at least one of an outer shape of a local area including the cutout in the peripheral edge portion 13 of the substrate 10, the peripheral edge position of the substrate 10, and the position of the center of gravity of the substrate 10.

In Step S313, the control unit 130 carries the substrate 10 from the substrate holding unit 120 to a target position using a substrate carrying mechanism (a substrate carrying robot) which is not illustrated. At this time, the control unit 130 can control positioning of the substrate 10 when the substrate 10 is carried from the substrate holding unit 120 to the target position on the basis of the position of the substrate 10 determined in Step S112. For example, the control unit 130 can calculate amounts of eccentricity of the positions X, Y, and θZ of the substrate 10 with respect to the substrate holding unit 120 on the basis of the position of the substrate 10 determined in Step S112 and control positioning of the substrate 10 on the basis of the amounts of eccentricity. The positioning of the substrate 10 can be controlled such that the substrate 10 is located at a predetermined position and in a predetermined direction.

In an embodiment, two or more types of measuring conditions may be different from each other in light intensity of light emitted from the light source unit 111 or may be different from each other in wavelength of the light. The light intensity in the measuring conditions may be set to the transmittance of the substrate. When two or more light source units 111 are provided, the two or more types of measuring conditions may be different from each other in irradiation angle of light from the light source unit 111. Here, different irradiation angles of light means, for example, that a first light source unit emits light from below the substrate 10 and a second light source unit emits light laterally or obliquely with respect to the substrate 10. Here, for example, when the substrate 10 is an opaque substrate 26 in which a transparent film 22 is bonded to the top surface as illustrated in FIG. 5, light from below the substrate 10 passes through the transparent film 22 and thus a light intensity of a part of the light decreases (that is, the light attenuates). However, regarding the lateral or oblique light, since light scattered by the peripheral edge 27 of the opaque substrate 26 and the peripheral edge 23 of the transparent film 22 is received by the light receiving unit 112, the peripheral edge 12 of the substrate 10 can be detected without attenuation of light. For example, the two or more types of measuring conditions may be different from each other in threshold value of the light intensity which can be measured by the light receiving unit 112. Here, the threshold value for the light intensity which can be measured by the light receiving unit 112 can also be referred to as a range of the light intensity which can be measured by the light receiving unit 112. For example, in the example illustrated in FIG. 4, light with an intensity which is higher than a normal light intensity and higher than a predetermined intensity is emitted from the light source unit 111. When a part of light from the light source unit 111 passes through the transparent substrate, the light intensity of the part of the light at that time decreases (that is, the light attenuates). However, the emitted light has a light intensity which is higher than the threshold value of the light intensity which can be measured by the light receiving unit 112 and which is still higher than the threshold value even after the attenuation of light in the transparent substrate. In this case, by setting the threshold value of the light intensity which can be measured by the light receiving unit 112 to be high, it is possible to acquire a light intensity distribution with a shape in which the light intensity changes greatly with the peripheral edge 12 of the transparent substrate as a boundary. The plurality of types of measuring conditions has only to be different from each other in one of the light intensity, the wavelength, and the irradiation direction of the light source unit 111 and the threshold value of the light intensity which can be measured by the light receiving unit 112.

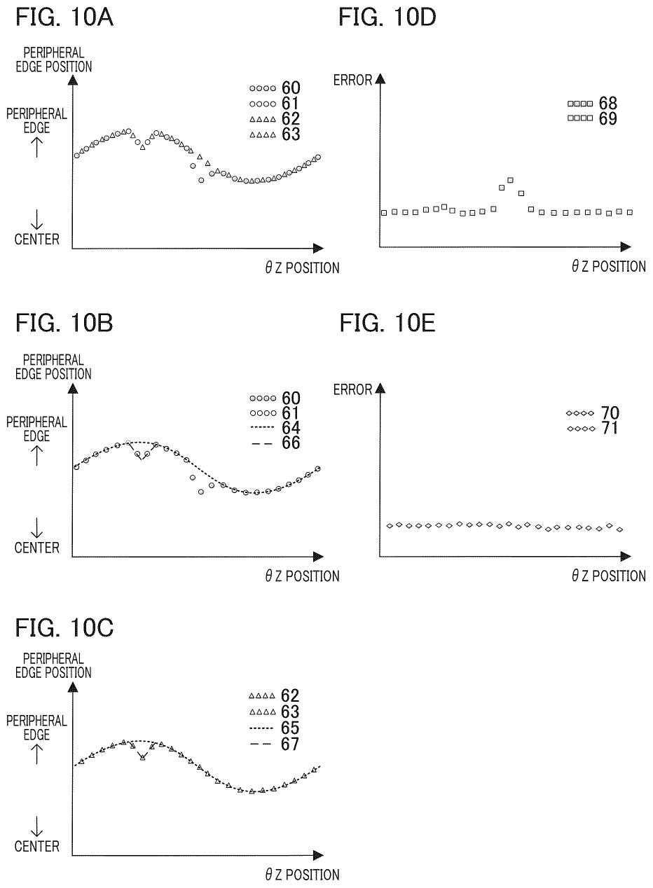

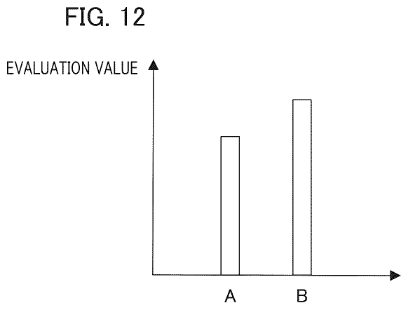

Steps S306 to S309 will be described below in more detail with reference to FIGS. 10A and 12. In Step S304, the control unit 130 controls the light source unit 111, for example, such that two or more types of measuring conditions, that is, a plurality of types of measuring conditions, are switched periodically and alternately while measuring the light intensity distribution. The control unit 130 acquires measurement results of the light intensity distribution measured while periodically and alternately switching the plurality of types of measuring conditions. For example, it is assumed that the plurality of types of measuring conditions include a measuring condition A and a measuring condition B. For example, the measuring condition A and the measuring condition B are different from each other in light intensity of light emitted from the light source unit 111. It is assumed that the light intensity of light emitted from the light source unit 111 in the measuring condition A is a normal light intensity and the light intensity of light emitted from the light source unit 111 in the measuring condition B has an intensity higher than a predetermined light intensity.

In Step S306, as illustrated in FIG. 10A, a position waveform 60 and a partial waveform 61 measured in the measuring condition A and a position waveform 62 and a partial waveform 63 measured in the measuring condition B are acquired periodically and alternately. In Step S306, the control unit 130 classifies the measurement results illustrated in FIG. 10A into the position waveform 60 and the partial waveform 61 measured in the measuring condition A illustrated in FIG. 10B and the position waveform 62 and the partial waveform 63 measured in the measuring condition B illustrated in FIG. 10C. In this way, the position waveform 60 and the partial waveform 61 in the measuring condition A and the position waveform 62 and the partial waveform 63 in the measuring condition B can be acquired.

In Step S307, the control unit 130 calculates an ideal position waveform 64 illustrated in FIG. 10B from the position waveform 60 corresponding to the measuring condition A and calculates an ideal position waveform 65 illustrated in FIG. 10C from the position waveform 62 corresponding to the measuring condition B.

In Step S308, as illustrated in FIG. 10D, the control unit 130 evaluates an error 68 between the position waveform 60 and the ideal position waveform 64 and an error 69 between the partial waveform 61 and the ideal partial waveform 66 in the measuring condition A and calculates an evaluation value thereof. As illustrated in FIG. 10E, the control unit 130 evaluates an error 70 between the position waveform 62 and the ideal position waveform 65 and an error 71 between the partial waveform 63 and the ideal partial waveform 67 in the measuring condition B and calculates an evaluation value thereof. That is, the control unit 130 calculates an evaluation value for each of a plurality of types of measuring conditions.

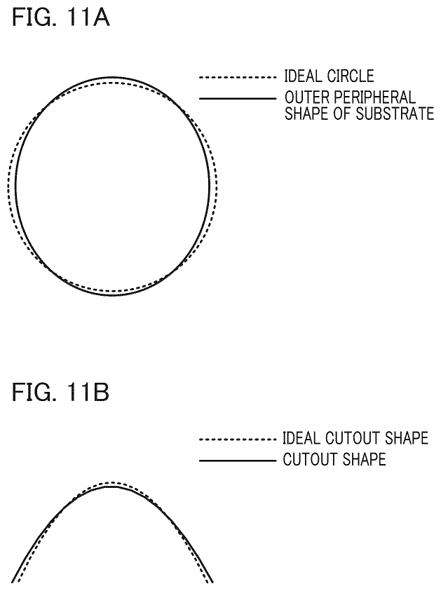

In Step S308, when the measuring condition A is evaluated, the control unit 130 calculates an outer shape of the substrate 10 as a substrate outer peripheral shape from the position waveform 60 and calculates an ideal circle (a first reference shape) from the ideal position waveform 64 as illustrated in FIG. 11A. Accordingly, the control unit 130 can calculate the evaluation value on the basis of the similarity between the position waveform 60 and the ideal position waveform 64 acquired from an error between the substrate outer peripheral shape and the ideal circle and/or the roundness of the substrate outer peripheral shape. When the measuring condition A is evaluated, the control unit 130 calculates an outer shape of the cutout (which may be hereinafter referred to as a cutout shape) of the substrate 10 as a substrate outer peripheral shape from the partial waveform 61 and calculates an ideal cutout shape (a second reference shape) from the ideal partial waveform 66 as illustrated in FIG. 11B. Accordingly, the control unit 130 can calculate the evaluation value on the basis of the similarity between the partial waveform 61 and the ideal partial waveform 64 acquired from an error between the cutout shape and the ideal cutout shape. This evaluation value is calculated for each measuring condition. FIG. 12 schematically illustrates evaluation values calculated for a plurality of types of measuring conditions A and B.

In Step S309, the control unit 130 can select one measuring condition (the measuring condition B in FIG. 12) with the best evaluation value out of the plurality of types of measuring conditions A and B as an optimal measuring condition on the basis of the evaluation values calculated for the measuring conditions A and B.

Specifically, for example, it is assumed that the substrate 10 is a substrate including an opaque substrate (for example, a silicon substrate) and a transparent film bonded thereon and the transparent film protrudes from the outer periphery of the silicon substrate. The measuring condition A is imaging with a normal light intensity, and the measurement result in the measuring condition A is the same as illustrated in FIG. 5. On the other hand, the measuring condition B is imaging with a higher light intensity than a normal light intensity, and the measurement result in the measuring condition B is the same as illustrated in FIG. 6. In this case, since the evaluation value in the measuring condition B is better than that in the measuring condition A, the control unit 130 sets the measuring condition B as an optimal measuring condition. As a result, in Steps S310 to S313, the control unit 130 causes the light source unit 111 to emit light with a light intensity in the measuring condition B.

As described above, the substrate processing device 100 according to the present embodiment acquires a plurality of types of light intensity distributions through one time of measurement by performing measurement while periodically and alternately switching a plurality of types of measuring conditions in one time of measurement of alight intensity distribution. Then, the substrate processing device 100 identifies a peripheral edge position candidate for each of the acquired light intensity distributions and selects one measuring condition used to determine the position of the substrate 10 out of the plurality of types of measuring conditions as an optimal measuring condition on the basis of the plurality of peripheral edge position candidates. According to the present embodiment, it is possible to appropriately select an optimal measuring condition using the light intensity distributions acquired through one time of measurement even when the process of measuring the light intensity distribution using the measurement unit 110 while rotationally driving the substrate 10 is not performed a plurality of times while changing the type of the measuring condition. That is, it is possible to make the throughput and the detection accuracy compatible at the time of detection of the position of the substrate 10.

In the aforementioned embodiment, the light intensity distributions in the plurality of types of measuring conditions have been acquired through one time of measurement by performing measurement while periodically and alternately switching the plurality of types of measuring conditions. However, for example, a plurality of measurement units 110, that is, a plurality of light source units 111 and a plurality of light receiving units 112, may be provided in the substrate processing device 100, and the light intensity distributions may be measured in different measuring conditions using the plurality of measurement units 110 through one time of measurement. In other words, a plurality of types of measurement results are acquired in parallel using the plurality of measurement units 110. With this configuration, it is possible to acquire light intensity distributions in a plurality of types of measuring conditions through one time of measurement.

In the aforementioned embodiment, a light intensity distribution is measured in a state in which the substrate 10 is being rotationally driven in the θZ direction by the substrate holding unit 120 (the rotational driving unit 121). However, for example, when a local protrusion of the transparent film 22 is detected, measurement of a light intensity distribution may be performed in a state in which the substrate 10 has been stopped. When a local peripheral edge position of a substrate is detected such as when the local protrusion of the transparent film 22 is detected, measurement of a light intensity distribution can be performed while switching two or more types of measuring conditions two or more times.

### Second Embodiment

A second embodiment of the present disclosure will be described below. The present embodiment basically succeeds to the first embodiment and conforms to the first embodiment except for description mentioned below. The same constituents will be referred to by the same reference signs, and description thereof will be omitted. The configuration of the substrate processing device illustrated in FIG. 1 will not be described similarly.

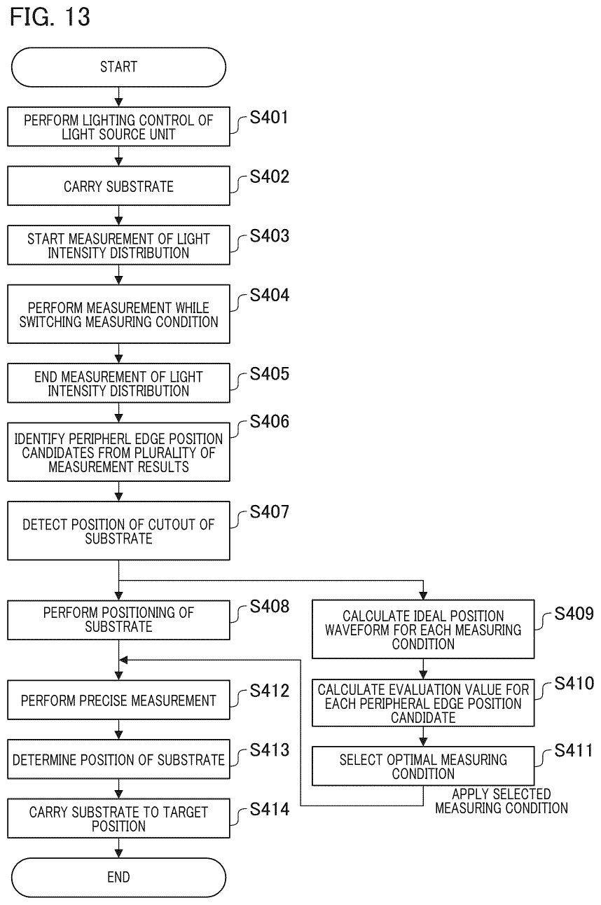

FIG. 13 is a flowchart illustrating an operation flow of a pre-alignment process according to the second embodiment. The flowchart illustrated in FIG. 13 can be performed by the control unit 130. Steps S401 to S406 in the flowchart of FIG. 13 are the same as Steps S301 to S306 in the flowchart illustrated in FIG. 9, and thus detailed description thereof will be omitted.

In Step S407, the control unit 130 detects a position of a peripheral edge portion 13 (for example, a cutout) of the substrate 10 held by the substrate holding unit 120. Detection of the position of the peripheral edge portion 13 in Step S407 may be performed on the basis of the peripheral edge position candidates acquired using predetermined measuring conditions or may be performed on the basis of the peripheral edge position candidates acquired using the measuring condition used in the previous determination step. The measuring condition used in the previous determination step may be a measuring condition used in a previous lot or a measuring condition used for a previous substrate.

In Step S408, the control unit 130 performs positioning of the substrate 10 such that the peripheral edge portion 13 (the cutout) of the substrate 10 is disposed in an optical path of the measurement unit 110 on the basis of the position of the peripheral edge portion 13 (the cutout) of the substrate 10 detected in Step S407. The positioning of the substrate 10 may be performed by translationally driving and rotational driving the substrate 10 using the substrate holding unit 120 or may be performed by placing the substrate 10 on the substrate holding unit 120 again using a substrate carrying mechanism (a substrate carrying robot) which is not illustrated.

Steps S409 to S411 are performed in parallel with Step S408. In Step S409, the control unit 130 calculates the eccentricity (X, Y) and the rotational angle θ of the substrate 10 with respect to the rotation center 125 of the substrate 10 using the substrate holding unit 120 on the basis of the position waveform 50 for each measuring condition as described above in the first embodiment. Accordingly, the ideal position waveform 52 for each measuring condition is calculated.

In Step S410, the control unit 130 calculates an evaluation value for each of a plurality of peripheral edge position candidates. Subsequently, in Step S411, the control unit 130 selects one measuring condition used to determine the position of the substrate 10 out of a plurality of types of measuring conditions as an optimal measuring condition on the basis of the evaluation values calculated for the peripheral edge position candidates in Step S410. Steps S409 to S411 are the same as Steps S307 to S309 in the flowchart of FIG. 9, and thus detailed description thereof will be omitted.

In Step S412, the control unit 130 performs precise measurement of re-measuring the light intensity distribution of the peripheral edge portion 13 of the substrate 10 under the optimal measuring condition using the measurement unit 110. In the precise measurement according to the present embodiment, since positioning of the substrate 10 has been performed in advance in Step S408, only the process of sequentially measuring the light intensity distribution of the peripheral edge portion 13 of the substrate 10 using the measurement unit 110 while rotationally driving the substrate 10 using the substrate holding unit 120 can be performed. Step S412 is the same as Step S311 in the flowchart of FIG. 9, and thus detailed description thereof will be omitted.

In Step S413, the control unit 130 determines the position of the substrate 10. Specifically, the control unit 130 identifies a peripheral edge position of the substrate 10 from the light intensity distribution acquired under the optimal measuring condition in Step S412. Subsequently, in Step S414, the control unit 130 carries the substrate 10 from the substrate holding unit 120 to a target position using a substrate carrying mechanism (a substrate carrying robot) which is not illustrated. Steps S413 and S414 are the same as Steps S312 and S313 in the flowchart of FIG. 9, and thus detailed description thereof will be omitted.

As described above, in the present embodiment, calculation of an evaluation value is performed in parallel with control of positioning of the substrate 10. Accordingly, it is possible to further improve the throughput of the substrate processing device 100.

### Third Embodiment

A third embodiment of the present disclosure will be described below. The present embodiment basically succeeds to the first embodiment and conforms to the first embodiment except for description mentioned below. The present embodiment may employ the second embodiment. The same constituents will be referred to by the same reference signs, and description thereof will be omitted. The configuration of the substrate processing device illustrated in FIG. 1 will not be described similarly.

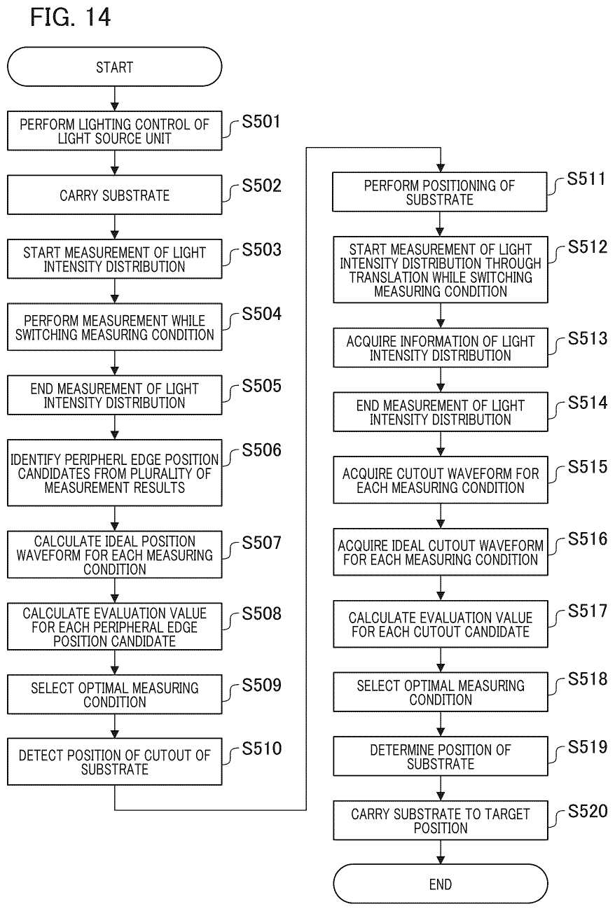

FIG. 14 is a flowchart illustrating an operation flow of a pre-alignment process according to the third embodiment. The flowchart illustrated in FIG. 14 can be performed by the control unit 130. Steps S501 to S510 in the flowchart of FIG. 14 are the same as Steps S301 to S310 in the flowchart illustrated in FIG. 9, and thus detailed description thereof will be omitted.

In Step S511, the control unit 130 performs positioning of the substrate 10 such that the peripheral edge portion 13 (the cutout) of the substrate 10 is disposed in an optical path of the measurement unit 110 on the basis of the position of the peripheral edge portion 13 (the cutout) of the substrate 10 detected in Step S510. The positioning of the substrate 10 may be performed by translationally driving and rotational driving the substrate 10 using the substrate holding unit 120 or may be performed by placing the substrate 10 on the substrate holding unit 120 again using a substrate carrying mechanism (a substrate carrying robot) which is not illustrated.

In Step S512, the control unit 130 starts translational driving of the substrate 10 in the X direction using the substrate holding unit 120 (the translational driving unit 122) and starts measurement of the light intensity distribution using the measurement unit 110. For example, while the substrate 10 is being translationally driven in the X direction by the substrate holding unit 120, the light receiving unit 112 (the light receiving element 112a) of the measurement unit 110 receives light from the light source unit 111 and continuously acquires the light intensity distribution of the peripheral edge portion 13 of the substrate 10 including a cutout in the X direction. Here, the light source unit 111 periodically switches two or more types of measuring conditions and the light receiving unit 112 continuously acquires the light intensity distribution of the peripheral edge portion 13 in the X direction in the plurality of types of measuring conditions. Here, the plurality of types of measuring conditions include, for example, the measuring condition A and the measuring condition B which are the same measuring conditions as in the first embodiment. In Step S512, the light intensity distribution of the cutout of the substrate 10 is measured by translationally driving the cutout of the substrate 10 in the X direction with respect to the optical path of the measurement unit 110.

In Step S513, the control unit 130 sequentially acquires information (data) of the light intensity distribution measured by the measurement unit 110 from the measurement unit 110 and stores the acquired information in the storage unit 133. Subsequently, in Step S514, the control unit 130 ends the translational driving of the substrate 10 and the measurement of the light intensity distribution in the measurement unit 110 when the substrate 10 has been translationally driven by an amount required for determining the position of the substrate 10.

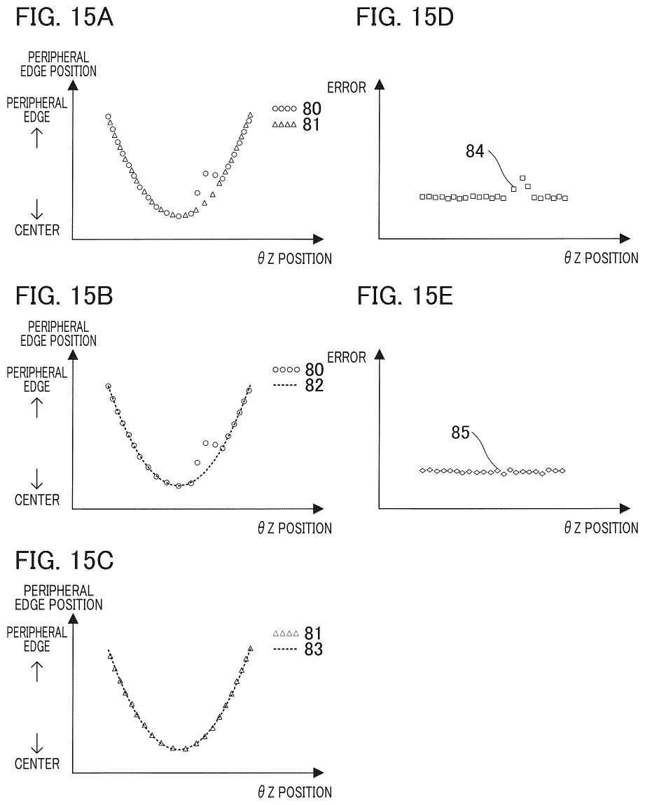

In Step S515, the control unit 130 identifies candidates for the position of the cutout (cutout position candidates) of the substrate 10 from the light intensity distributions under a plurality of types of measuring conditions sequentially acquired through Steps S512 to S514. Accordingly, the control unit 130 can acquire a cutout waveform illustrated in FIG. 15A for each measuring condition. The cutout waveform is a waveform corresponding to the cutout of the substrate 10. In FIG. 15A, the horizontal axis represents a position in the θZ direction of the peripheral edge portion 13 (that is, the rotational angle θ of the substrate 10) at which measurement of a light intensity distribution has been performed by the measurement unit 110, and the vertical axis represents a peripheral edge position in the radial direction identified from the light intensity distribution measured by the measurement unit 110. Here, as the cutout waveform, a cutout waveform 80 imaged in the measuring condition A and a cutout waveform 81 imaged in the measuring condition B are acquired periodically and alternately. The control unit 130 classifies the cutout waveforms illustrated in FIG. 15A into the cutout waveform 80 measured in the measuring condition A illustrated in FIG. 15B and the cutout waveform 81 measured in the measuring condition B illustrated in FIG. 15C and acquires the cutout waveform for each measuring condition.

In Step S516, the control unit 130 acquires an ideal cutout waveform 82 for the measuring condition A and an ideal cutout waveform 83 for the measuring condition B by performing curve approximation using a least square method on the cutout waveforms (the cutout waveform 80 and the cutout waveform 81 herein). The ideal cutout waveform 82 and the ideal cutout waveform 83 may be understood as indicating an ideal outer shape of the cutout of the substrate 10. In the present embodiment, a notch is mentioned as the cutout of the substrate 10, but the cutout of the substrate 10 may be an orientation flat. When the cutout of the substrate 10 is an orientation flat, the control unit 130 calculates an ideal cutout waveform by performing linear approximation using a least square method on the waveform corresponding to the cutout of the substrate 10.

In Step S517, the control unit 130 calculates an evaluation value for each of a plurality of cutout position candidates. For example, the control unit 130 calculates an error 84 between the cutout waveform 80 and the ideal cutout waveform 82 with respect to the rotational angle in the measuring condition A and calculates the evaluation value on the basis of the error 84 as illustrated in FIG. 15D. For example, the control unit 130 can calculate the evaluation value on the basis of a sum value or a variance value of the error 84. The evaluation value can be calculated for each measuring condition. FIG. 15E is a diagram illustrating an error 85 between the cutout waveform 81 and the ideal cutout waveform 83 with respect to the rotational angle in the measuring condition B.

In Step S518, the control unit 130 compares the evaluation values for the measuring conditions calculated in Step S517 and selects a measuring condition with the best evaluation value as an optimal measuring condition. The optimal measuring condition selected in Step S518 may be the same as the optimal measuring condition selected in Step S509 or may be different therefrom. The optimal measuring condition may be used for alignment of a second or later substrate in the same lot. When a measuring method of repeatedly performing measurement of the light intensity distribution in Steps S512 to S514 is performed, the optimal measuring condition selected in the first measurement may be used for the second or later measurement.

In Step S519, the control unit 130 determines the position of the substrate 10 using the optimal measuring condition selected in Step S518. Specifically, the control unit 130 identifies the peripheral edge position of the substrate 10 using the light intensity distribution acquired in the optimal measuring condition out of the light intensity distributions acquired through Steps S512 to S514. Then, the control unit 130 calculates a position waveform at the identified peripheral edge position of the substrate 10 and determines the position of the substrate 10 on the basis of the position waveform.

In Step S520, the control unit 130 carries the substrate 10 from the substrate holding unit 120 to a target position using a substrate carrying mechanism (a substrate carrying robot) which is not illustrated. At this time, the control unit 130 can control positioning of the substrate 10 when the substrate 10 is carried from the substrate holding unit 120 to the target position on the basis of the position of the substrate 10 determined in Step S519. Step S520 is the same as Steps S313 in the flowchart of FIG. 9, and thus detailed description thereof will be omitted.

In the present embodiment, it is also possible to make the throughput and the detection accuracy compatible at the time of detection of the position of the substrate 10 similarly to the first embodiment.

### Fourth Embodiment

A fourth embodiment of the present disclosure will be described below. The present embodiment basically succeeds to the first embodiment and conforms to the first embodiment except for description mentioned below. The present embodiment may employ the second embodiment or the third embodiment. The same constituents will be referred to by the same reference signs, and description thereof will be omitted. The configuration of the substrate processing device illustrated in FIG. 1 will not be described similarly.

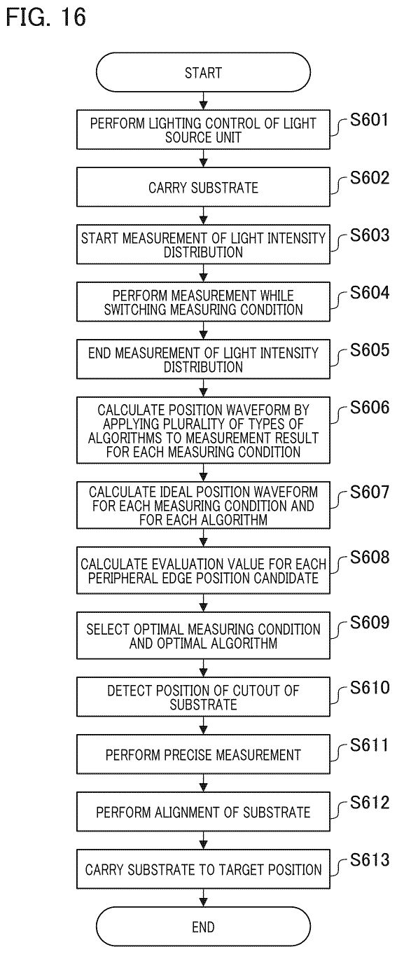

FIG. 16 is a flowchart illustrating an operation flow of a pre-alignment process according to the fourth embodiment. The flowchart illustrated in FIG. 16 can be performed by the control unit 130. Steps S601 to S605 in the flowchart of FIG. 16 are the same as Steps S301 to S305 in the flowchart illustrated in FIG. 9, and thus detailed description thereof will be omitted.

In Step S606, the control unit 130 identifies a plurality of peripheral edge position candidates from the light intensity distributions by applying a plurality of types of algorithms to the light intensity distributions for a plurality of types of measuring conditions acquired through Steps S603 to S605. Here, the peripheral edge position candidates corresponding to the number of types of measuring conditions x the number of types of algorithms can be identified. The plurality of types of algorithms are set to identify the peripheral edge position according to the types of the substrate 10 and are stored in the storage unit 133. The control unit 130 can identify a plurality of peripheral edge position candidates from the light intensity distribution in one type of measuring condition by reading a plurality of algorithms from the storage unit 133 and applying the plurality of types of algorithms to the light intensity distributions for the plurality of types of measuring conditions. Identification of the plurality of peripheral edge position candidates using the plurality of types of algorithms is performed for each of the light intensity distributions sequentially acquired through Steps S603 to S605.

Here, each of the plurality of types of algorithms may be set to detect (identify) the position of the peripheral edge 12 of the substrate 10 from the light intensity distributions measured by the measurement unit 110 for each type of the substrate 10 on which the pre-alignment process is to be performed by the substrate processing device 100. Specifically, for example, each algorithm may be an algorithm for detecting a peripheral edge 12 of an opaque substrate or may be an algorithm for detecting a peripheral edge 12 of a transparent substrate (for example, a glass substrate) which has not been chamfered. Each algorithm may be an algorithm for detecting a peripheral edge 12 of a bonded substrate including a transparent support substrate (for example, a glass substrate) and an opaque substrate (for example, a silicon substrate) bonded thereto. The plurality of types of algorithms may include, for example, at least two types of algorithms which are different from each other in determination threshold value for identifying the peripheral edge position of the substrate 10 from the light intensity distributions.

In Step S607, the control unit 130 calculates the eccentricity (X, Y) and the rotational angle θ of the substrate 10 with respect to the rotation center 125 of the substrate 10 using the substrate holding unit 120 on the basis of the position waveform for each measuring condition and each algorithm. Accordingly, it is possible to calculate an ideal position waveform for each measuring condition and each algorithm.

In Step S608, the control unit 130 calculates an evaluation value for each of a plurality of peripheral edge position candidates (an evaluation step). Step S608 is the same as Steps S308 in the flowchart of FIG. 9, and thus detailed description thereof will be omitted.

In Step S609, the control unit 130 selects one measuring condition and one algorithm used to determine the position of the substrate 10 out of a plurality of types of measuring conditions and a plurality of types of algorithms as an optimal measuring condition and an optimal algorithm on the basis of the evaluation value calculated for each peripheral edge position candidate in Step S608 (a selection step). For example, the control unit 130 can select a peripheral edge position candidate with the best evaluation value out of the plurality of peripheral edge position candidates and select a combination of a measuring condition and an algorithm used to identify the selected peripheral edge position candidate as the optimal measuring condition and the optimal algorithm. Specifically, when a sum value of the errors between the acquired position waveform and the ideal position waveform is calculated as the evaluation value, the control unit 130 can select a measuring condition and an algorithm used to identify the peripheral edge position candidate with the smallest evaluation value out of the plurality of peripheral edge position candidates as the optimal measuring condition and the optimal algorithm. On the other hand, when a reciprocal of a sum value of the errors between the position waveform and the ideal position waveform is calculated as the evaluation value, the control unit 130 can select a measuring condition and an algorithm used to identify the peripheral edge position candidate with the largest evaluation value out of the plurality of peripheral edge position candidates as the optimal measuring condition and the optimal algorithm.

Steps S610 to S613 constitute a step of controlling positioning of the substrate 10 using the measuring condition and the algorithm selected in Step S609. Steps S610 to S613 are the same as Steps S310 to S313 in the flowchart of FIG. 9, and thus detailed description thereof will be omitted.

As described above, in the present embodiment, measurement of a light intensity distribution is performed on a carried substrate using two or more types of measuring conditions, and two or more types of algorithms are applied to the acquired light intensity distributions. Accordingly, it is possible to select and apply an optimal measuring condition and an optimal algorithm for each type of the substrate. As a result, according to the present embodiment, it is possible to further improve the detection accuracy of the substrate processing device 100.

### <Embodiment of Lithography Device>

An embodiment of the lithography device according to the present embodiment will be described below. The lithography device is a device that is used for a lithography process which is a process of manufacturing a semiconductor device or a liquid crystal display device and forms a pattern on a substrate. An example of the lithography device is an exposure device that transfers a pattern of a reticle onto a substrate by exposing the substrate via the reticle. In the following description, an exposure device will be exemplified as the lithography device.

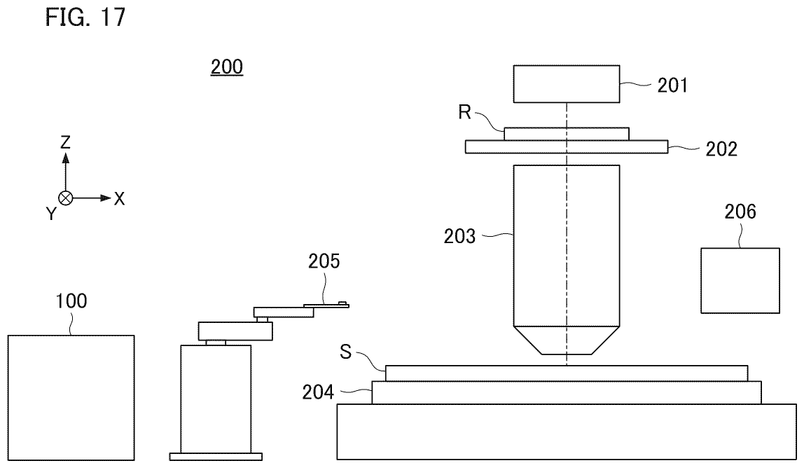

FIG. 17 is a diagram schematically illustrating an example of a configuration of an exposure device 200. For example, the exposure device 200 transfers a pattern of a reticle R onto a substrate S, for example, using a step-and-repeat system or a step-and-scan system. The exposure device 200 includes an illumination optical system 201, a reticle stage 202, a projection optical system 203, a substrate stage 204, a carrying device 205, and a control unit 206 as illustrated in FIG. 17. In the exposure device 200, the illumination optical system 201, the reticle stage 202, the projection optical system 203, and the substrate stage 204 serves as a formation unit that forms a pattern on the substrate S.

The exposure device 200 includes the aforementioned substrate processing device 100 that processes the substrate S. The substrate processing device 100 performs a pre-alignment process on the substrate S as a process of the substrate S. Then, the substrate S processed by the substrate processing device 100 is carried onto the substrate stage 204 by the carrying device 205. For example, the control unit 130 of the substrate processing device 100 controls positioning of the substrate S when the substrate S is carried onto the substrate stage 204 by the carrying device 205 on the basis of the position of the substrate S determined through the pre-alignment process of the substrate S. The control unit 206 of the exposure device 200 and the control unit 130 of the substrate processing device 100 may be provided as a unified body or as separate bodies.

### <Embodiment of Article Manufacturing Method>

The aforementioned lithography device can be used to embody an article manufacturing method for manufacturing various articles (such as a semiconductor IC device, a liquid crystal display device, and an MEMS). The article manufacturing method according to the embodiment of the present disclosure can be suitably used, for example, to manufacture an article such as a device (such as a semiconductor device, a magnetic storage medium, or a liquid crystal display device). The article manufacturing method includes a processing step of processing a substrate using the substrate processing method (the substrate processing device), a formation step of forming a pattern on the substrate undergoing the processing step, and a manufacturing process of manufacturing an article from the substrate undergoing the formation step. The processing step may be understood as a step of performing a pre-alignment process as processing of the substrate. The article manufacturing method includes other known steps (oxidation, film formation, vapor deposition, doping flattening, etching, resist removal, dicing, bonding, packaging and the like). The article manufacturing method according to the present embodiment is more advantageous in at least one of performance, quality, productivity, and production cost of an article in comparison with a method according to the related art.

### Other Embodiments

While embodiments of the present disclosure have been described above, the present disclosure is not limited to the embodiments and can be modified or altered in various forms within the scope of the gist thereof.

The present disclosure can be realized using a process of supplying a program for realizing one or more functions in the aforementioned embodiments to a system or a device via a network or a storage medium and causing one or more processors in a computer of the system or the device to read and execute the program. The present disclosure can also be realized by a circuit (for example, an ASIC) for realizing one or more functions.

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiments and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

According to the present disclosure, for example, it is possible to provide a technique which is advantageous for making the throughput and the detection accuracy compatible at the time of detection of a position of a substrate.

This application claims the benefit of Japanese Patent Application No. 2024-224827, filed Dec. 20, 2024, which is herein in its entirety.

What is claimed is:

1. A substrate processing method of processing a substrate, the substrate processing method comprising:
performing a measurement of a light intensity distribution which is acquired from a peripheral edge portion of the substrate when the peripheral edge portion is irradiated with light from a light source unit; and
identifying candidates for a peripheral edge position of the substrate on the basis of a result of the performing the measurement,
wherein a plurality of types of the results of the measurement are acquired by performing the measurement using a plurality of types of measuring conditions in one time of the measurement, and the candidates are identified from the plurality of types of the results of the performing the measurement.

2. The substrate processing method according to claim 1, wherein the measurement is performed in the plurality of types of measuring conditions by switching the plurality of types of measuring conditions at least two or more times or periodically in the measurement.

3. The substrate processing method according to claim 1, wherein at least the peripheral edge portion of the substrate is irradiated with the light while rotationally driving the substrate in the measurement.

4. The substrate processing method according to claim 1, further comprising selecting one measuring condition which is used to determine a position of the substrate out of the plurality of types of measuring conditions on the basis of the plurality of identified candidates.

5. The substrate processing method according to claim 4, further comprising calculating an evaluation value for each of the plurality of identified candidates,
wherein one measuring condition is selected out of the plurality of types of measuring conditions on the basis of the evaluation value calculated for each of the plurality of candidates.

6. The substrate processing method according to claim 5, wherein the evaluation value is calculated on the basis of similarity between an outer shape of the substrate acquired from the peripheral edge position and a first reference shape for each of the plurality of candidates.

7. The substrate processing method according to claim 5, wherein the evaluation value is calculated on the basis of roundness of an outer shape of the substrate acquired from the peripheral edge position for each of the plurality of candidates.

8. The substrate processing method according to claim 5, wherein the evaluation value is calculated on the basis of similarity between a shape of a cutout of the substrate acquired from the peripheral edge position and a second reference shape for each of the plurality of candidates.

9. The substrate processing method according to claim 5, further comprising:
positioning the substrate such that the peripheral edge portion of the substrate is disposed on an optical path of the light from the light source unit and performing a re-measurement of the light intensity distribution acquired from the peripheral edge portion under the selected one measuring condition; and
determining the position of the substrate on the basis of the result of the re-measurement,
wherein the calculating of the evaluation value is performed in parallel with the positioning of the substrate.

10. The substrate processing method according to claim 9, wherein the selecting of the one measuring condition is performed in parallel with the positioning of the substrate.

11. The substrate processing method according to claim 9, wherein the positioning of the substrate is performed on the basis of the identified candidates for the peripheral edge position according to a preset measuring condition or a previous measuring condition used to determine the position of the substrate out of the plurality of types of measuring conditions.

12. The substrate processing method according to claim 1, wherein the plurality of types of measuring conditions are different from each other in light intensity of the light from the light source unit.

13. The substrate processing method according to claim 1, wherein the plurality of types of measuring conditions are different from each other in wavelength of the light from the light source unit.

14. The substrate processing method according to claim 1, wherein the plurality of types of measuring conditions are different from each other in irradiation direction of the light from the light source unit.

15. The substrate processing method according to claim 1, wherein the plurality of types of measuring conditions are different from each other in threshold value for a light intensity which can be measured by a light receiving unit.

16. The substrate processing method according to claim 1, wherein the plurality of candidates are identified by applying a plurality of types of algorithms to the plurality of types of results of the measurement.

17. An article manufacturing method comprising:
performing measurement of a light intensity distribution which is acquired from a peripheral edge portion of a substrate when the peripheral edge portion is irradiated with light from a light source unit;
identifying candidates for a peripheral edge position of the substrate on the basis of a result of the performing the measurement,
wherein a plurality of types of the results of the measurement are acquired by performing the measurement using a plurality of types of measuring conditions in one time of the measurement, and the candidates are identified from the plurality of types of the results of the performing the measurement,
forming a pattern on the substrate; and
manufacturing an article from the substrate on which the pattern has been formed.

18. A substrate processing device that processes a substrate, the substrate processing device comprising:
a measurement unit configured to measure a light intensity distribution which is acquired from a peripheral edge portion of the substrate when the peripheral edge portion is irradiated with light; and
a control unit configured to control positioning of the substrate,
wherein the control unit acquires a plurality of types of the results of measurement by causing the measurement unit to perform a measurement using a plurality of types of measuring conditions in one time of the measurement and identifies candidates for a peripheral edge position of the substrate from each of the plurality of types of results of measurement.

19. The substrate processing device according to claim 18, wherein the measurement unit includes a plurality of light source units and a plurality of light receiving units.

20. A lithography device that forms a pattern on a substrate, the lithography device comprising:
a substrate processing device that includes:
a measurement unit configured to measure a light intensity distribution which is acquired from a peripheral edge portion of the substrate when the peripheral edge portion is irradiated with light; and
a control unit configured to control positioning of the substrate,
wherein the control unit acquires a plurality of types of the results of measurement by causing the measurement unit to perform a measurement using a plurality of types of measuring conditions in one time of the measurement and identifies candidates for a peripheral edge position of the substrate from each of the plurality of types of results of measurement; and
a formation unit configured to form the pattern on the substrate processed by the substrate processing device.
